(19) United States
(12) Patent Application Publication
(10) Pub. No.: US 2025/0185450 A1
(43) Pub. Date: Jun. 5, 2025

(54) Large Scale Solution Processible Polycrystalline Perovskite for Low-Cost Pixelated X-ray Imager

(71) Applicant: Chemelectronics LLC, Inglewood, CA (US)

(72) Inventors: Michelle B. Li, Inglewood, CA (US); Michael Li, Inglewood, CA (US); Lili Zhou, Inglewood, CA (US); Huaping Li, Inglewood, CA (US)

(73) Assignee: Chemelectronics LLC, Inglewood, CA (US)

(21) Appl. No.: 18/965,729

(22) Filed: Dec. 2, 2024

Related U.S. Application Data
(60) Provisional application No. 63/101,183, filed on Dec. 4, 2023.

(51) Int. Cl. H10K 39/36; C09K 11/66; H10K 39/38; H10K 85/50

(52) U.S. Cl. CPC H10K 39/36; C09K 11/665; H10K 39/38; H10K 85/50

(57) ABSTRACT

The disclosure provides low-cost solution processible polycrystalline all-inorganic perovskite CsPb8r3 integrated on silicon thin film transistor panels for pixelated X-ray imagers. Some embodiments demonstrate 10-100 keV x-ray energy range with detection sensitivity of >100 μC Gyair−1 cm−2 at pixel size less than 100 micrometers.

### CROSS-REFERENCE TO RELATED APPLICATIONS

The present application is a continuation of U.S. patent application Ser. No. 18/527,831 entitled “Large Scale Solution Processible Polycrystalline Perovskite for Low-Cost Pixelated X-ray Imager” to Li et al., filed Dec. 4, 2023, the disclosure of which is incorporated herein by reference in their entireties

### GOVERNMENT RIGHTS STATEMENT

This invention was made with government support under the Grant Number DE-S00022471 awarded by a SBIR/STTR grant. The government has certain rights in the invention.

### FIELD OF THE INVENTION

This application generally relates to low-cost solution processible polycrystalline all-inorganic perovskite CsPb8r3 integrated on silicon thin film transistor panel for pixelated X-ray imager, and more specifically to such imagers with 10-100 keV x-ray energy range with a detection sensitivity of >100 μC Gyₐᵢᵣ⁻¹ cm⁻² at a pixel size less than 100 micrometers.

### BACKGROUND

Low cost, high resolution and high sensitivity x-ray imager would benefit medical diagnosis and safety screening in public areas.

### SUMMARY OF THE INVENTION

Devices and methods in accordance with some embodiments of the invention are directed to medical imagers devices and methods for their manufacture and use.

Various embodiments are directed to pixelated X-ray imagers including, polycrystalline all-inorganic perovskite CsPb8r3 integrated on silicon thin film transistors.

In still various embodiments the imagers have an x-ray energy range of 10-100 keV.

In yet various embodiments the imagers have a detection sensitivity of >100 μC Gyₐᵢᵣ⁻¹ cm⁻² at pixel size less than 100 micrometers.

Additional embodiments and features are set forth in part in the description that follows and, in part, will become apparent to those skilled in the art upon examination of the specification or may be learned by the practice of the disclosure. A further understanding of the nature and advantages of the present disclosure may be realized by reference to the remaining portions of the specification and the drawings, which form a part of this disclosure.

### BRIEF DESCRIPTION OF THE DRAWINGS

The description will be more fully understood with reference to the following figures, which are presented as embodiments of the invention and should not be construed as a complete recitation of the scope of the invention wherein:

FIG. 1 provides a solution for the growth of the CsPb8r3 polycrystalline orange powder in accordance with embodiments.

FIG. 2 provides an x-Ray powder diffraction pattern of CsPb8r3 polycrystalline powder, where the inset is an XRD pattern of CsPb8r3 single crystal, in accordance with some embodiments.

FIG. 3 provides a TGA weight loss plot of CsPb8r3 polycrystalline orange powder (left) and CsPb8r3 single crystal (right), in accordance with some embodiments.

FIG. 4 provides a photographic image of solution recrystallization of CsPb8r3 polycrystals on ITO glass in Petri Dish, in accordance with some embodiments.

FIG. 5 provides a photographic image of solution recrystallized CsPbBr3 films on ITO glass and measured thickness, in accordance with some with some embodiments.

FIG. 6 provides processes for making CsPbBr3 thin films on ITO glass through pressing and solution annealing for 1 hour, in accordance with some embodiments.

FIG. 7 provides photographic images of CsPb8r3 thin films through pressing wet CsPbBr3 slurry on ITO glass and annealed on hot plate at 80° C. for 1 hour, in accordance with some embodiments.

FIG. 8 provides photographic images of CsPb8r3 thin films through direct solution driven precipitation on ITO glass and annealed on hot plate at 80° C. for 1 hour, in accordance with some embodiments.

FIG. 9 provides optic images of CsPbBr3 thin films prepared from Method 2, where the top set was lower magnitude (×5) and bottom set higher magnitude (×40), in accordance with embodiments.

FIG. 10 provides optic images of CsPb8r3 thin films prepared from Method 2, where the top set was lower magnitude (×5) and bottom set higher magnitude (×40), in accordance with embodiments.

FIG. 11 provides photographic images of ITO/CsPb8r3/gold diode illuminated with white and UV LED, in accordance with embodiments.

FIG. 12 provides the current-bias curves with linear scale (left) and logarithmic scale (right) of ITO/CsPbBr3/gold diode illuminated under white and UV LED, in accordance with embodiments.

FIG. 13 provides photographic images of 2 inch×2 inch 100 μm pixel size x-ray imager backplane (left), coated with polycrystalline CsPbBr3 thin film (middle), and further deposited with 16 patterned gold electrodes (right), in accordance with embodiments.

### DETAILED DESCRIPTION OF THE INVENTION

It will be understood that the components of the embodiments, as generally described herein and illustrated in the appended figures, may be arranged and designed in a variety of different configurations. Thus, the following more detailed description of various embodiments, as represented in the figures, is not intended to limit the scope of the present disclosure but is merely representative of various embodiments. While various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages and similar language throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment. Thus, the phrases “in one embodiment,” “in an embodiment,” and similar language throughout this specification may but do not necessarily, all refer to the same embodiment.

Various embodiments in accordance with the disclosure provide low-cost solution processible polycrystalline all-inorganic perovskite CsPb8r3 integrated on silicon thin film transistor panels for pixelated X-ray imager. Some embodiments demonstrate 10-100 keV x-ray energy range with detection sensitivity of >100 μC Gyₐᵢᵣ⁻¹ cm⁻² at pixel size less than 100 micrometers.

Several embodiments of solution processible low-cost polycrystalline CsPb8r3 perovskite are inspired by their excellent carrier mobility and lifetime, as well as free of deep trap states. The demonstrated benefits of low-cost pixelated x-ray imager with polycrystalline CsPb8r3 perovskite include high resolution, sensitivity and stability. Furthermore, the use of low-cost polycrystalline CsPb8r3 perovskite materials and a solution-processed procedure will meet the cost target of<$0.5/cm3 for the x-ray active materials.

Many embodiments: (1) identify the solution engineering process protocols for the low-cost polycrystalline CsPb8r3 perovskite; and (2) integrate polycrystalline CsPb8r3 perovskite with silicon thin film transistor panel to characterize pixelated x-ray imager performance in sensitivity and operational stability. Multiple iterations of embodiments optimize the engineering of polycrystalline CsPb8r3 perovskite to achieve high x-ray detection sensitivity.

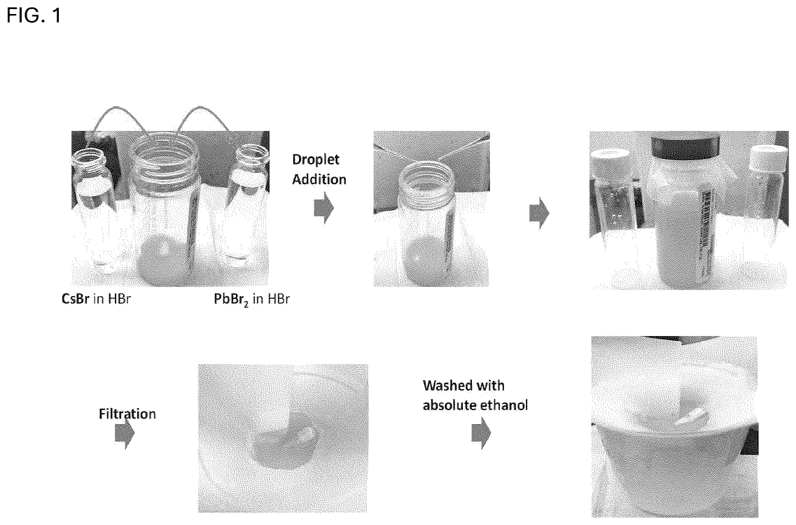

Various embodiments demonstrate different ways to grow polycrystalline CsPb8r3. The first effort is to produce CsPb8r3 polycrystal orange powder. Several batches of solution growth of CsPbBr3 polycrytal orange powder were conducted are summarized in FIG. 1. Briefly, commercially available lead(II) bromide (PbBr2, 99.999%) and cesium bromide (CsBr, 99.999%) were supplied by Alfa Aesar. Aqueous hydrobromic acid (HBr, 48 wt % in H₂O, 99.9999% metal basis) was purchased from Fisher Scientific. PbBr₂ (20 mmol, 7.34 g) and CsBr (20 mmol, 4.26 g) were respectively dissolved in hydrobromic acid [40 ml each 48% HBr(aq)] in separate beakers to form PbBr₂ and CsBr solutions in advance. Then the solutions were simultaneously added dropwise into 5 ml of 48% aqueous HBr with stirring during the synthesis reaction. The precipitation reaction is as follows:

$${PbBr}_{2} + CsBr = CsPb 8 r 3 J$$

A bright orange precipitate of CsPb8r3 immediately formed in the aqueous HBr solution. The precipitate was filtered, copiously rinsed three times with absolute ethyl alcohol and then dried under vacuum to obtain orange CsPb8r3 polycrystalline powder.

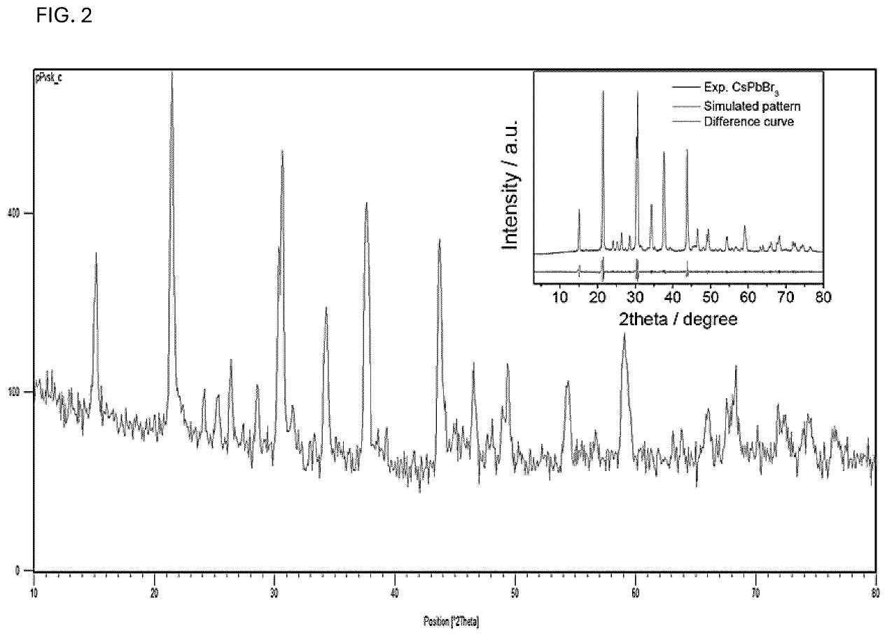

The CsPb8r3 polycrystalline powder was characterized using x-ray powder diffraction. The obtained result is presented in FIG. 2, which is same as the XRD pattern obtained for CsPb8r3 single crystal previously published (inset of FIG. 2).

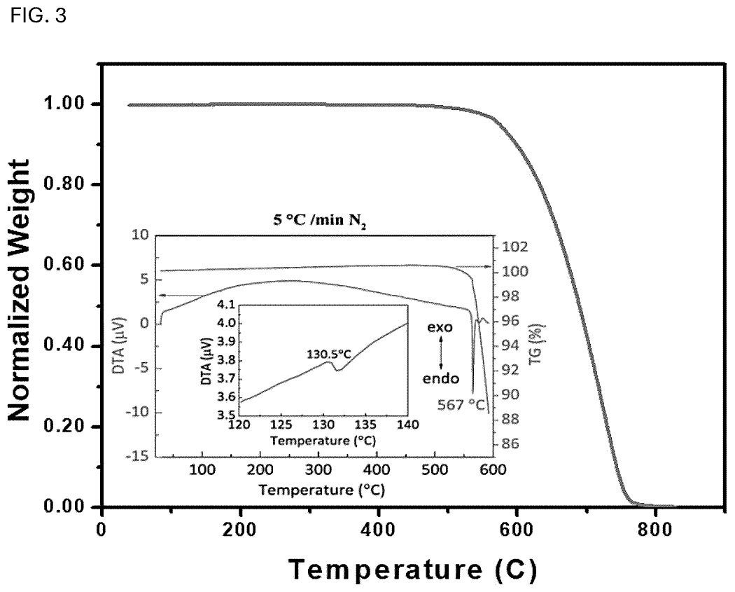

CsPb8r3 polycrystalline orange powder was also characterized using Thermogravimetric Analysis (TGA). The TGA weight loss plot was shown in FIG. 3 (left), consistent with the thermal weight loss of CsPb8r3 single crystal published in literature (right of FIG. 3).

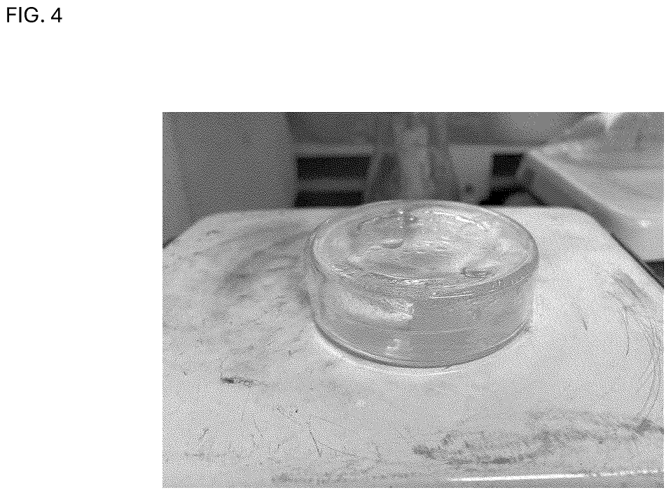

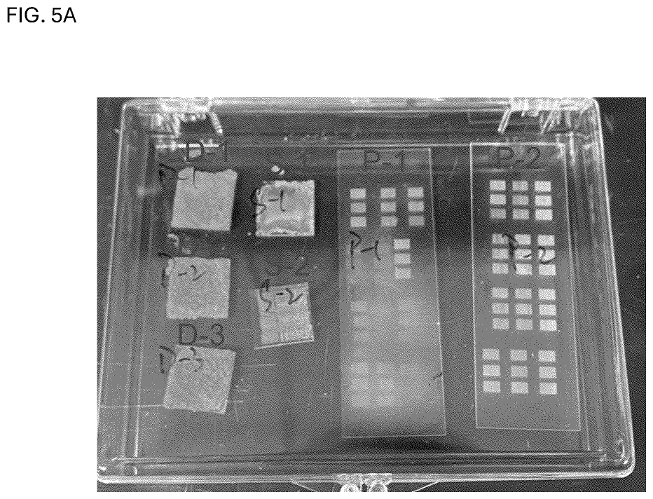

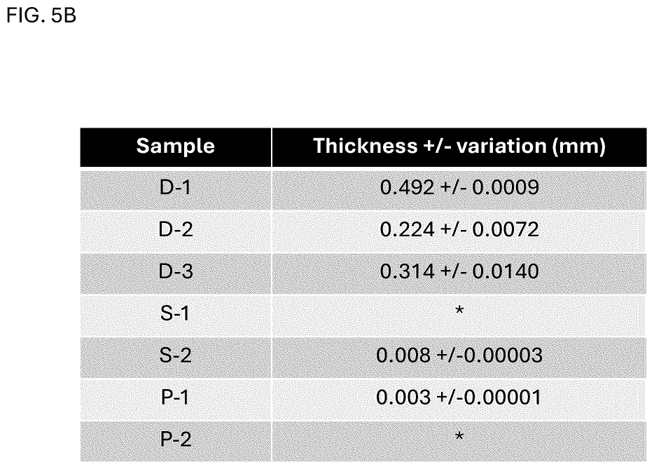

In various embodiments CsPb8r3 polycrystalline powder were recrystallized using solution method. The CsPb8r3 polycrystalline powder (3.6 gram) were dissolved in 6 ml DMSO in a petri dish. The solution was heated on hotplate at 140° C. Then the cleaned ITO glass was placed in CsPb8r3 DMSO solution (FIG. 4). A large amount of single cubic single crystalline CsPb8r3 films were obtained. These CsPb8r3 single crystals were disorganized on the surface of ITO. There are apparent gaps between cubic CsPb8r3 single crystals (FIG. 5). The thickness of these CsPb8r3 films ranged from 0.2 mm to 0.5 mm.

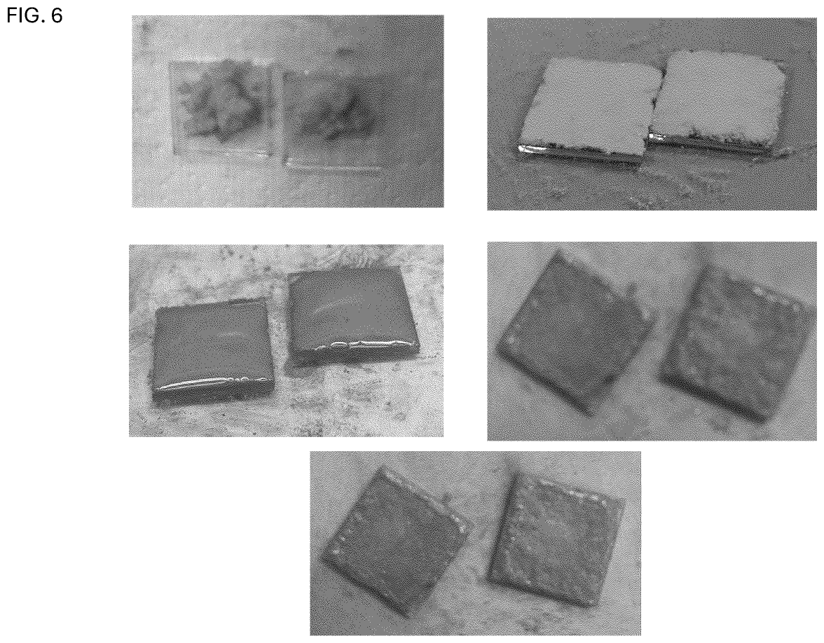

In various other embodiments CsPbBr3 polycrystalline powder was placed on ITO glass and press them into thin films. Then saturated CsPb8r3 DMSO solution was dropped on the pressed CsPb8r3 thin films. Then the CsPbBr3 thin films were annealed on hot plate at 80 cc. The nice CsPbBr3 thin films were obtained (FIG. 6).

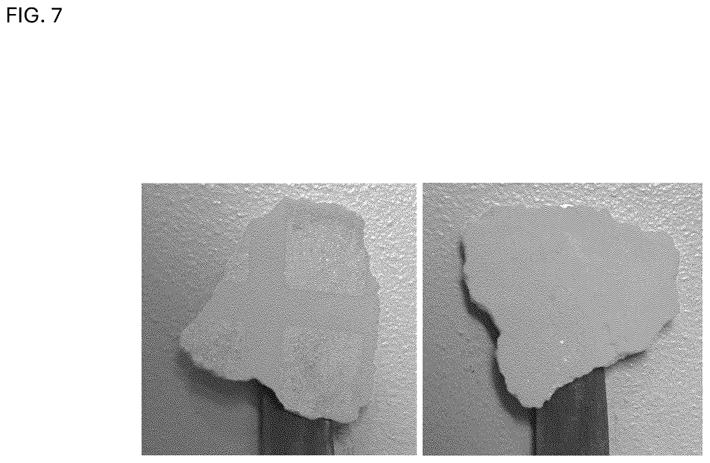

In still various embodiments the wet CsPb8r3 slurry during synthesis before washing and dry can be pressed into CsPbBr3 thin films and annealed on hot plate at 80 cc for one hour, and CsPbBr3 thin films were obtained (FIG. 7).

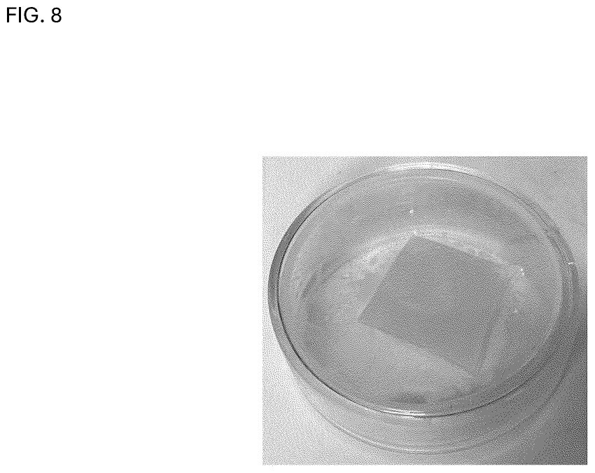

In yet various embodiments the 1.064 gram CsBr and 3.67 gram PbBr₂ were dissolved in 15 ml DMSO. The solution was heated on a hotplate at 70° C. The solution was transferred to the devices on hotplate at 70° C. Then chlorobenzene was dropped onto the desired areas. The yellowish materials were precipitated onto the targeted area to form thin films. The obtained CsPb8r3 thin films were annealed at 80° C. for 1 hour (FIG. 8).

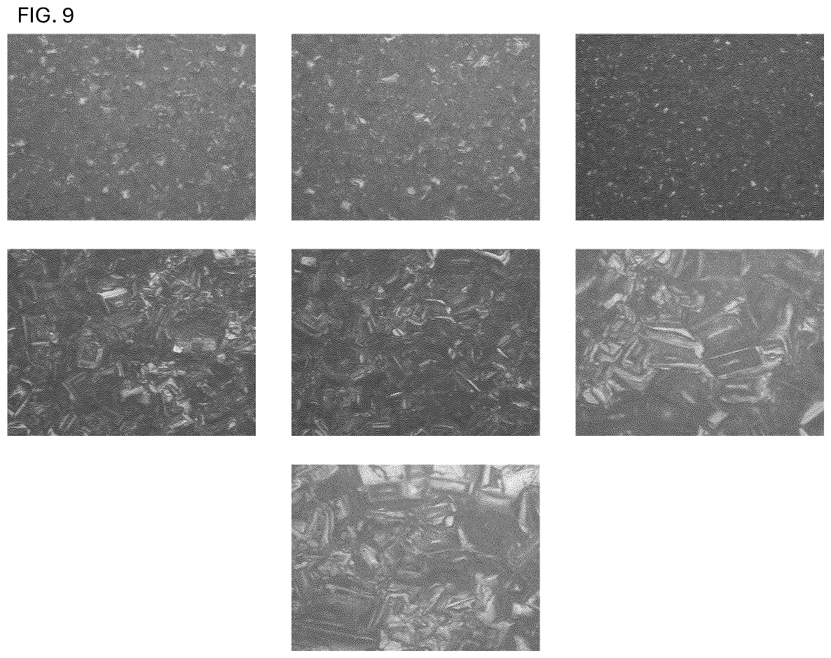

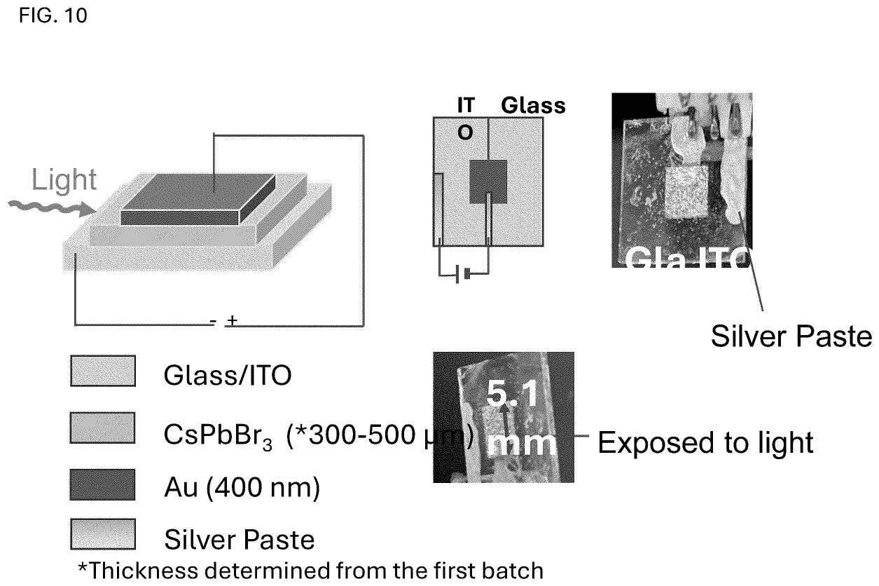

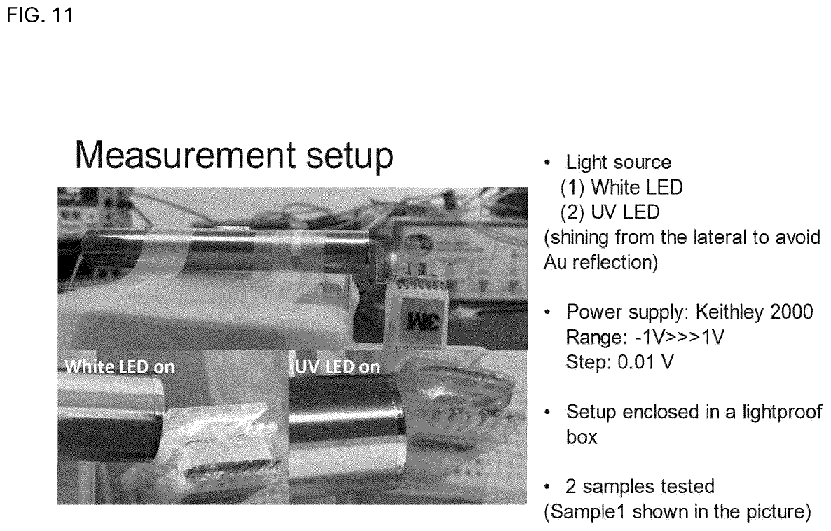

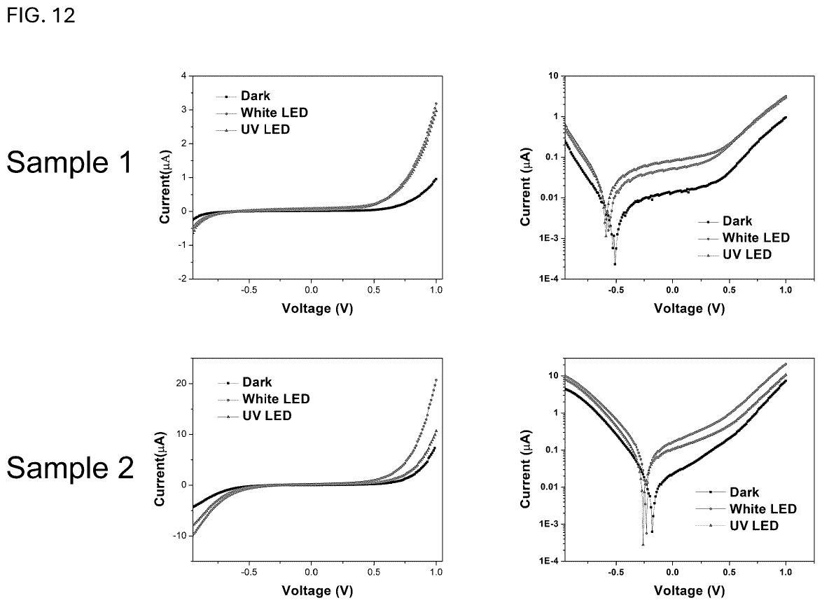

The CsPb8r3 thin films prepared in accordance with FIG. 6 were analyzed with optic microscopy. As shown in FIG. 9, the smooth surfaces with crystalline boundary. The prepared CsPbBr3 thin films in accordance with FIG. 6 were deposited with gold electrode. The device photographic images and device structure are shown in FIG. 10. The fabricated devices were measured under UV light and white light illumination as presented in FIG. 11. The measured current-bias curves are shown in FIG. 12. The obtained results show the photocurrent is three times of dark current under 1 volt bias.

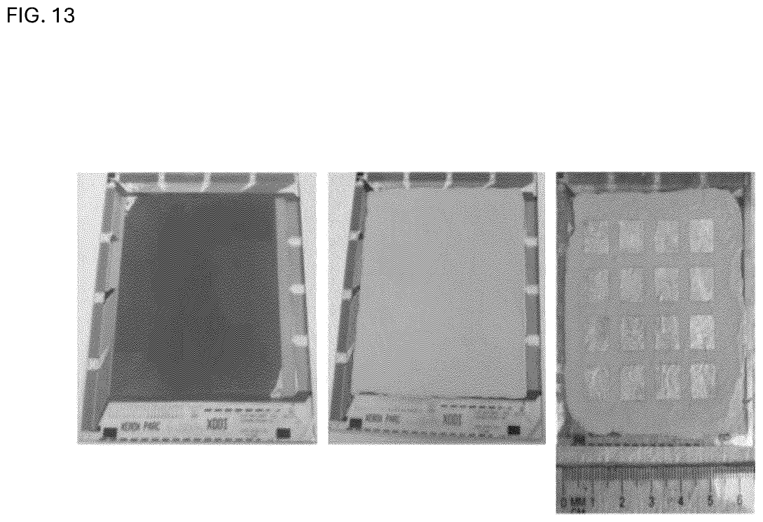

In several embodiments CsPb8r3 polycrystalline thin film was deposited on a 100 μm pixel size array (2 inch×2 inch) fabricated by Palo Alto Research Center Inc. (PARC) as shown in FIG. 13. Then CsPb8r3 polycrystalline thin film was prepared using the method provided in FIG. 6 twice, FIG. 7 twice, and FIG. 8 once. On these prepared CsPbBr3 polycrystalline thin film, 16 gold electrodes were patterned in a clean room for x-ray imager test undergoing at PARC.

Using various embodiments according to the disclosure it is possible to provide a low-cost solution processible polycrystalline all-inorganic perovskite CsPb8r3 integrated on silicon thin film transistor panel for pixelated X-ray imager. Such imagers demonstrate 10-100 keV x-ray energy range with detection sensitivity of>100 μC Gyₐᵢᵣ−1 cm−2 at pixel size less than 100 micrometers. The demonstrated benefits of low-cost pixelated x-ray imager with polycrystalline CsPb8r3 perovskite include high resolution, sensitivity and stability. Furthermore, the use of low-cost polycrystalline CsPb8r3 perovskite materials and a solution-processed procedure will meet the cost target of<$0.5/cm3 for the x-ray active materials. The low cost, high resolution and high sensitivity x-ray imager will benefit the medical diagnosis and safety screening in public areas.

### Doctrine of Equivalents

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to +0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

1. A pixelated X-ray imager comprising
a one or more silicon thin film transistors; and
a polycrystalline perovskite CsPbBr3 film, wherein the polycrystalline perovskite CsPbBr3 film comprises a plurality of CsPbBr3 polycrystals, and wherein the plurality of CsPbBr3 polycrystals crystalizes on the one or more silicon thin film transistors to form a polycrystalline perovskite CsPbBr3 film integrated on the one or more silicon thin film transistors.

2. The pixelated X-ray imager of claim 1, wherein the imagers has an x-ray energy range of 10-100 keV.

3. The pixelated X-ray imager of claim 1, wherein the imagers has a detection sensitivity of >100 μC Gyₐᵢᵣ⁻¹ cm⁻² at a pixel size less than 100 micrometers.

4. The pixelated X-ray imager of claim 1, further comprising a one or more gold electrodes patterned between the one or more silicon thin film transistors and the polycrystalline perovskite CsPbBr₃ film.

5. The pixelated X-ray imager of claim 1, wherein the plurality of CsPbBr3 polycrystals are configured in an irregular pattern on the one or more silicon thin film transistors.

6. The pixelated X-ray imager of claim 1, wherein the polycrystalline perovskite CsPbBr₃ film has a thickness range of 0.2 mm to 0.5 mm.

7. A method of fabricating a pixelated X-ray imager comprising:
providing a plurality of CsPbBr₃ polycrystals;
pressing a plurality of CsPbBr₃ polycrystals on a CsPbBr₃ thin film on a one or more silicon backplane;
dissolving the plurality of CsPbBr₃ polycrystals in a Dimethyl Sulfoxide (DMSO) solution;
wetting the pressed plurality of CsPbBr₃ polycrystals using the DMSO and dissolved CsPbBr₃ polycrystal solution;
recrystallizing the wetted pressed plurality of CsPbBr₃ polycrystals, wherein the pressed plurality of CsPbBr₃ polycrystals is configured to recrystallize on the one or more silicon backplane; and
annealing the recrystallized plurality of CsPbBr₃ polycrystals using an industrial exciton laser.

8. The method of claim 7, the step of provided the plurality of CsPbBr₃ polycrystals comprises:
dissolving a plurality of crystalline PbBr₂ in a first aqueous solution comprising at least 40% by weight HBr;
dissolving a plurality of crystalline CsBr in a second aqueous solution comprising at least 40% by weight HBr; and
mixing the first aqueous solution and the second aqueous solution in 1:1 molar ratio.

9. The method of claim 7, wherein the pixelated X-ray imager has an x-ray energy range of 10-100 keV.

10. The method of claim 7, wherein the pixelated X-ray imager has a detection sensitivity of >100 μC Gyₐᵢᵣ⁻¹ cm⁻² at a pixel size less than 100 micrometers.

11. The method of claim 7, further comprising patterning a one or more gold electrodes between the one or more silicon thin film transistors and the plurality of recrystallized CsPbBr₃ polycrystals.

12. The method of claim 7, wherein the plurality of CsPbBr₃ polycrystals are configured in an irregular pattern on the one or more silicon thin film transistors.

13. The method of claim 7, wherein the plurality of recrystallized CsPbBr₃ polycrystals has a thickness range of 0.2 mm to 0.5 mm.
